(19) United States
(12) Patent Application Publication
(10) Pub. No.: US 2015/0236294 A1
(43) Pub. Date: Aug. 20, 2015

(54) Organic optoelectronic component, method for producing an organic optoelectronic component and method for cohesive electrical contacting

(71) Applicant: OSRAM OLED GMBH, Regensburg (DE)

(72) Inventors: Simon Schicktanz, Regensburg (DE); Philipp Schwamb, Regensburg (DE); Evelyn Trummer-Sailer, Mintraching (DE)

(21) Appl. No.: 14/430,575

(22) PCT Filed: Sep. 25, 2013
(86) PCT No.: PCT/EP2013/069916

§ 371 Date: Mar. 24, 2015

(30) Foreign Application Priority Data
Sep. 27, 2012 (DE) 10 2012 109 161.7

(51) Int. Cl. H01L 51/52; H01L 27/30; H01L 27/32; H01L 51/56; H01L 51/44

(52) U.S. Cl. CPC H01L 51/5206; H01L 51/56; H01L 51/5221; H01L 51/524; H01L 51/441; H01L 51/448; H01L 27/3276; H01L 27/3288; H01L 27/301

(57) ABSTRACT

An organic optoelectronic component may include at least one contact pad with a first electrical contact region and a second electrical contact region. The first electrical contact region and the second electrical contact region are electrically connected to the contact pad. The second electrical contact region is designed in such a way that it has a higher adhesion than the first electrical contact region in respect of a cohesive connection means with the contact pad. The contact pad is designed in such a way that the first electrical contact region is free of cohesive connection means.

### RELATED APPLICATIONS

The present application is a national stage entry according to 35 U.S.C. §371 of PCT application No.: PCT/EP2013/069916 filed on Sep. 25, 2013, which claims priority from German application No.: 10 2012 109 161.7 filed on Sep. 27, 2012, and is incorporated herein by reference in its entirety.

### TECHNICAL FIELD

In various embodiments, an organic optoelectronic component, a method for producing an organic optoelectronic component and a method for cohesive electrical contacting are provided.

### BACKGROUND

An organic optoelectronic component, for example an organic light emitting diode (OLED), includes at least two electrodes and an organic functional layer system therebetween. The electrodes are electrically connected to contact pads, wherein the contact pads are usually arranged at the geometrical edge of the OLED. An electrical terminal is coupled, i.e. electrically contacted, to the contact pads and thereby supplies the organic functional layer system with current.

The contact pads conventionally include, on account of established manufacturing processes, metal layer stacks, for example chromium-aluminum-chromium (Cr—Al—Cr). The exposed surface of said metal layer stacks, for example chromium, on account of the constitution thereof, is not solderable with conventional solders, since, for example, the exposed chromium surface and the soldering tin are not compatible with one another, for example are immiscible. Arbitrary flowing of the soldering tin on the chromium surface of the contact pad occurs as a result. The flowing soldering tin then makes it more difficult to precisely position the terminals on the soldering location.

In one conventional method, a soldering resist or soldering pad forms (constrictions) is/are used for restricting the solderable regions.

In another conventional method, a flexible printed circuit board (flex-PCB) is connected to a contact pad by means of an electrically conductive adhesive bond (anisotropic conductive film bonding—ACF bonding), wherein a flex-PCB in turn provides a soldering pad for further electrical contacting.

In a further conventional method, for the purpose of electrical contacting, a wire is connected to a contact pad by means of a friction welding process (ultrasonic bonding—US bonding).

In one conventional method, the electrical contacting is realized by means of clamping contacts, for example by means of spring pins and corresponding clamping mounts.

A further problem in the case of electrical contacting is posed by the polarity reversal, incorrect polarity or short-circuiting of an organic optoelectronic component in the case of similarly shaped poles, for example contact pads.

### SUMMARY

In various embodiments, an organic optoelectronic component, a method for producing an organic optoelectronic component and a method for cohesive electrical contacting are provided which make it possible to form a solderability of contact pads for electrically contacting the contact pads and additionally to realize a soldering resist function.

In the context of this description, an organic substance can be understood to mean a carbon compound which, regardless of the respective state of matter, is present in chemically uniform form and is characterized by characteristic physical and chemical properties. Furthermore, in the context of this description, an inorganic substance can be understood to mean a compound which, regardless of the respective state of matter, is present in chemically uniform form and is characterized by characteristic physical and chemical properties, without carbon or a simple carbon compound. In the context of this description, an organic-inorganic substance (hybrid substance) can be understood to mean a compound which, regardless of the respective state of matter, is present in chemically uniform form and is characterized by characteristic physical and chemical properties, including compound portions which contain carbon and are free of carbon. In the context of this description, the term “substance” encompasses all abovementioned substances, for example an organic substance, an inorganic substance, and/or a hybrid substance. Furthermore, in the context of this description, a substance mixture can be understood to mean something which has constituents consisting of two or more different substances, the constituents of which are very finely dispersed, for example. A substance class should be understood to mean a substance or a substance mixture including one or more organic substance(s), one or more inorganic substance(s) or one or more hybrid substance(s). The term “material” can be used synonymously with the term “substance”.

In the context of this description, a first substance or a first substance mixture can be identical to a second substance or a second substance mixture, respectively, if the chemical and physical properties of the first substance or first substance mixture are identical to the chemical and physical properties of the second substance or of the second substance mixture, respectively.

In the context of this description, a first substance or a first substance mixture can be similar to a second substance or a second substance mixture, respectively, if the first substance or the first substance mixture and the second substance or the second substance mixture, respectively, have an approximately identical stoichiometric composition, approximately identical chemical properties and/or approximately identical physical properties with regard to at least one variable, for example the density, the refractive index, the chemical resistance or the like.

In this respect, by way of example, with regard to the stoichiometric composition crystalline SiO₂ (quartz) can be regarded as identical to amorphous SiO₂ (silica glass) and as similar to SiOₓ. However, with regard to the refractive index, crystalline SiO₂ can be different than SiOₓ or amorphous SiO₂. By means of the addition of additives, for example in the form of dopings, by way of example, amorphous SiO₂ can have a refractive index which is identical or similar to that of crystalline SiO₂, but can then be different than crystalline SiO₂ with regard to the chemical composition and/or the chemical resistance.

The reference variable in terms of which a first substance is similar to a second substance can be indicated explicitly or become apparent from the context, for example from the common properties of a group of substances or substance mixtures.

The dimensional stability of a geometrically formed substance can be understood with the aid of the modulus of elasticity and the viscosity.

In various embodiments, a substance can be regarded as dimensionally stable, i.e. in this sense as hard and/or solid, if the substance has a viscosity in a range of approximately 5×10² Pa·s to approximately 1×10²³ Pa·s and a modulus of elasticity in a range of approximately 1×10⁶ Pa to approximately 1×10¹² Pa, since the substance can exhibit a viscoelastic to brittle behavior after the formation of a geometrical form.

A substance can be regarded as formable, i.e. in this sense as soft and/or liquid, if the substance has a viscosity in a range of approximately 1×10⁻² Pa·s to approximately 5×10² Pa·s or a modulus of elasticity of upto approximately 1×10⁶ Pa, since any change in the geometrical form of the substance can lead to an irreversible plastic change in the geometrical form of the substance.

A dimensionally stable substance can become plastically formable, i.e. can be liquefied, by means of the addition of plasticizers, for example solvent, or by means of the temperature being increased.

A plastically formable substance can become dimensionally stable, i.e. can be solidified, by means of a crosslinking reaction, withdrawal of plasticizers and/or heat.

Solidifying a substance or substance mixture, i.e. the transition of a substance from formable to dimensionally stable, may include changing the viscosity, for example increasing the viscosity from a first viscosity value to a second viscosity value. The second viscosity value can be greater than the first viscosity value by a multiple, for example in a range of approximately 10 to approximately 10⁶. The substance can be formable at the first viscosity and dimensionally stable at the second viscosity.

Solidifying a substance or substance mixture, i.e. the transition of a substance from formable to dimensionally stable, may include a method or a process in which low molecular weight constituents are removed from the substance or substance mixture, for example solvent molecules or low molecular weight, uncrosslinked constituents of the substance or of the substance mixture, for example drying or chemically crosslinking the substance or the substance mixture. The substance or the substance mixture can have for example, in the formable state a higher concentration of low molecular weight substances in the overall substance or substance mixture than in the dimensionally stable state.

A body composed of a dimensionally stable substance or substance mixture can be formable, however, for example if the body is designed as a film, for example a plastics film, a glass film or a metal film. Such a body can be referred to as mechanically flexible, for example, since changes in the geometrical shape of the body, for example bending of a film, can be reversible. A mechanically flexible body, for example a film, can also be plastically formable, however, for example by means of the mechanically flexible body being solidified after the deformation, for example thermoforming of a plastics film.

The connection of a first body to a second body can be positively locking, force locking and/or cohesive. The connections can be embodied as releasable, i.e. reversible. In various configurations, a reversible, cohesive connection can be realized for example as a screw connection, a hook and loop fastener, a clamping/a use of clips.

However, the connections can also be embodied as non-releasable, i.e. irreversible. In this case, a non-releasable connection can be separated only by means of the connection means being destroyed. In various configurations, an irreversible, close connection can be realized for example as a riveted connection, an adhesively bonded connection or a soldered connection.

In the case of a positively locking connection, the movement of the first body can be restricted by a surface of the second body, wherein the first body moves perpendicularly, i.e. normally, in the direction of the restricting surface of the second body. A pin (first body) in a blind hole (second body) can be restricted in movement for example in five of the six spatial directions. In various configurations, a positively locking connection can be realized for example as a screw connection, a hook and loop fastener, a clamp/a use of clips.

In the case of a force-locking connection, in addition to the normal force of the first body on the second body, i.e. a physical contact of the two bodies under pressure, a static friction can restrict a movement of the first body parallel to the second body. One example of a force-locking connection may be, for example, the self-locking of a screw in a complementarily formed thread. Self-locking in this case can be understood to mean a resistance by means of friction. In various configurations, a force-locking connection can be realized for example as a screw connection, a riveted connection.

In the case of a cohesive connection, the first body can be connected to the second body by means of atomic and/or molecular forces. Cohesive connections can often be non-releasable connections. In various configurations, a cohesive connection can be realized for example as an adhesively bonded connection, a solder connection, for example of a glass solder, or of a metal solder, a welded connection.

Close fixing can be understood, for example, as close connection of an organic optoelectronic component to a holder. In various configurations, cohesive fixing can be realized by means of a close connection means, for example a fusible connector. The quality, i.e. the degree, of the close fixing can be a function of the wetting of a liquefied fusible connector on the first body and/or the second body. Generally, wetting is a behavior of liquids upon contact with the surface of solids. The degree of the close fixing can for example also be designated as wettability or else, depending on the application, solderability, adhesive-bondability or the like. A liquid can wet a surface to different extents depending on the material constitution of the liquid, for example the atomic interaction properties; the material constitution and topographical constitution, for example the roughness, of the wetted surface and the interfacial tension between the wetted surface and the liquid. By means of Young's equation, the relationship can be related via the contact angle and thus make the latter the measure of wettability. In this case, the greater the contact angle, the lower the wettability.

In the context of this description, a close connection means, for example a fusible connector, can be a substance or substance mixture for cohesively connecting two bodies, for example an organic optoelectronic component to a holder.

In various configurations, a fusible connector can be a substance which is dimensionally stable at room temperature up to approximately 80° C. and which, for connecting the bodies, firstly is liquefied and then is solidified again. In this case, the fusible connector can be brought into contact with the two bodies as early as before liquefaction or only in the formable, for example liquid, state. In various configurations, the fusible connector can be liquefied in a convection furnace, a reflow furnace or by means of local heating, for example by means of laser irradiation. In various configurations, the fusible connector may include a plastic, for example a synthetic resin, and/or a metal, for example a solder. In various configurations, the solder may include an alloy. In various configurations, the solder may include one of the following substances: lead, tin, zinc, copper, silver, aluminum, silicon and/or glass and/or organic or inorganic additives.

In the context of this description, electrical contacting can be understood as forming an electrical contact between an electrical connection structure and a contact pad, an electrode and/or an electrical connection layer.

In the context of this description, an electronic component can be understood to mean a component which concerns the control, regulation or amplification of an electric current, for example by means of the use of semiconductor components. An electronic component can be for example a diode, a transistor, a thermogenerator, an integrated circuit or a thyristor.

In the context of this description, an optoelectronic component can be understood to mean an embodiment of an electronic component, wherein the optoelectronic component includes an optically active region.

In the context of this description, an optically active region of an optoelectronic component can be understood to mean that region of an optoelectronic component which can absorb electromagnetic radiation and form a photocurrent therefrom or can emit electromagnetic radiation by means of a voltage applied to the optically active region.

In the context of this description, providing electromagnetic radiation can be understood to mean emitting electromagnetic radiation.

In the context of this description, taking up electromagnetic radiation can be understood to mean absorbing electromagnetic radiation.

An optoelectronic component whose optically active region includes two planar, optically active sides can be embodied for example as transparent, for example as a transparent organic light emitting diode. However, the optically active region can also include one planar, optically active side and one planar, optically inactive side, for example an organic light emitting diode designed as a top emitter or bottom emitter.

In various configurations, an optoelectronic component which emits electromagnetic radiation can be for example a semiconductor component which emits electromagnetic radiation, and/or can be embodied as a diode which emits electromagnetic radiation, as an organic diode which emits electromagnetic radiation, as a transistor which emits electromagnetic radiation or as an organic transistor which emits electromagnetic radiation. The radiation can be light in the visible range, UV light and/or infrared light, for example. In this connection, the component which emits electromagnetic radiation can be embodied for example as a light emitting diode (LED), as an organic light emitting diode (OLED), as a light emitting transistor or as an organic light emitting transistor. In various configurations, the light emitting component can be part of an integrated circuit. Furthermore, a plurality of light emitting components can be provided, for example in a manner accommodated in a common housing.

In the context of this description, an organic optoelectronic component, for example an organic light emitting diode (OLED), an organic photovoltaic installation, for example an organic solar cell; in the organic functional layer system may include or be formed from an organic substance or an organic substance mixture which is designed for example for providing electromagnetic radiation from an electric current provided or for providing an electric current from electromagnetic radiation provided.

In the context of this description, a harmful environmental influence can be understood to mean all influences which for example can potentially result in degradation, crosslinking, and/or crystallization of the organic substance or of the organic substance mixture and can thus limit the operating period of organic components, for example.

A harmful environmental influence can be for example a substance which is harmful to the organic substances or organic substance mixtures, for example oxygen and/or for example a solvent, for example water.

A harmful environmental influence can be for example surroundings which are harmful to organic substances or organic substance mixtures, for example a change above or below a critical value, for example of the temperature, and/or a change in the ambient pressure.

In various embodiments, an organic optoelectronic component is provided, the organic optoelectronic component including: at least one contact pad with a first electrical contact region and a second electrical contact region; wherein the first electrical contact region and the second electrical contact region are electrically connected to the contact pad; and wherein the second electrical contact region is designed in such a way that it has a higher adhesion than the first electrical contact region in respect of a cohesive electrical connection of the contact pad.

In one configuration of the organic optoelectronic component, the first electrical contact region can be designed for force-locking and/or positively locking electrical contacting of the contact pad.

In one configuration of the organic optoelectronic component, the second electrical contact region can be designed for close electrical contacting of the contact pad, for example cohesive, force-locking and/or positively locking electrical contacting.

In one configuration of the organic optoelectronic component, the first electrical contact region can be formed alongside the second electrical contact region.

In one configuration of the organic optoelectronic component, the first electrical contact region can at least partly laterally surround the second electrical contact region, for example in a ring-shaped or planar fashion.

In one configuration of the organic optoelectronic component, the second electrical contact region can have a larger layer thickness than the first electrical contact region.

In one configuration of the organic optoelectronic component, the second electrical contact region can be elevated relative to the first electrical contact region, wherein elevation can be understood as topographical elevation.

In one configuration of the organic optoelectronic component, the second electrical contact region can have an adhesion promoter layer as an exposed layer. The adhesion promoter layer can be formed in such a way that the adhesion between a cohesive connection means and the layer on or above which the adhesion promoter layer is formed is increased, for example by reduction of the adhesion work of the cohesive connection means during wetting, as a result of which the degree of wetting is increased.

In one configuration of the organic optoelectronic component, the adhesion promoter layer can be formed in an electrically conductive fashion. The adhesion promoter layer can therefore also be designated as a second electrically conductive layer.

In one configuration of the organic optoelectronic component, the second layer structure can be formed in such a way that the adhesion promoter layer is electrically connected, for example cohesively connected, to the contact pad.

In one configuration of the organic optoelectronic component, the second electrical contact region can have a greater or lesser surface roughness than the first electrical contact region in such a way that the second electrical contact region has a larger contact area than the first electrical contact region in respect of the cohesive connection.

In one configuration of the organic optoelectronic component, the adhesion promoter layer may include or be formed from one of the following substances: gold, silver, copper, platinum, palladium, nickel, aluminum.

In one configuration of the organic optoelectronic component, the first electrical contact region can have an electrically conductive layer as an exposed layer, for example may include or be formed from chromium or aluminum. An exposed layer can also be designated or understood as an uncovered layer or exposed surface of a layer structure.

In one configuration of the organic optoelectronic component, the first electrical contact region can have a dielectric layer, for example a barrier thin-film layer, as an exposed layer.

In one configuration of the organic optoelectronic component, the first electrical contact region and the second electrical contact region can be formed on or above a common, electrically conductive substrate.

In one configuration of the organic optoelectronic component, at least one part of the adhesion promoter layer of the second layer structure can be formed on or above the dielectric layer. By way of example, the second contact region can be laterally surrounded by the first contact region, for example in the form of a structured dielectric layer, wherein no dielectric layer is formed in the second electrical contact region and the adhesion promoter layer of the second contact region overfills the structured dielectric layer.

In one configuration of the organic optoelectronic component, the part of the adhesion promoter layer on or above the dielectric layer can be cohesively and/or electrically connected to the second electrical contact region.

In one configuration of the organic optoelectronic component, the adhesion promoter layer can be cohesively connected to the dielectric layer in such a way that the physical contact of the first electrical contact region with the second electrical contact region is at least partly hermetically sealed with regard to at least water and/or oxygen, for example by the adhesion promoter layer being cohesively connected to the dielectric layer.

In one configuration of the organic optoelectronic component, the second layer structure may include the adhesion promoter layer and at least partly the first layer structure; by way of example, the second layer structure can be formed as an adhesion promoter layer on or above the first layer structure and/or, by way of example, the adhesion promoter layer can be formed on or above an exposed, electrically conductive region of the first layer structure. The part of the first layer structure as part of the second layer structure should have no dielectric layer in the current path of the second layer structure.

In one configuration of the organic optoelectronic component, the second electrical contact region can be designed for spatially delimiting the cohesive electrical contacting of the contact pad, for example as a soldering resist.

In one configuration of the organic optoelectronic component, the organic optoelectronic component can furthermore include an optically active region and an optically inactive region. The optically inactive region can be formed for example in a planar fashion alongside the optically active region, for example laterally at least partly surround the optically active region in a planar fashion.

In one configuration of the organic optoelectronic component, the optically active region can have an electrically active region, for example an organic functional layer structure and at least one electrode.

In one configuration of the organic optoelectronic component, the contact pad can be formed at least partly in the optically inactive region, for example substantially or completely; by way of example, a part of an electrode of the electrically active region or of a connection layer which is electrically connected to an electrode of the electrically active region can be designed as a contact pad.

In one configuration of the organic optoelectronic component, the optically active region and the optically inactive region can be formed in such a way that the contact pad is electrically connected to the electrically active region, for example by the contact pad being electrically connected to the at least one electrode.

In one configuration of the organic optoelectronic component, the organic optoelectronic component can be formed as an organic solar cell or an organic light emitting diode.

In various embodiments, a method for producing an organic optoelectronic component is provided, the method including: providing a contact pad having a first electrical contact region and a second electrical contact region; increasing the adhesion of the second electrical contact region compared with the first electrical contact region in respect of a cohesive electrical connection of a connection structure to the contact pad.

In one configuration of the method, the first electrical contact region can be formed alongside the second electrical contact region.

In one configuration of the method, the second electrical contact region can be formed in such a way that the first electrical contact region at least partly laterally surrounds the second electrical contact region, for example in a ring-shaped or planar fashion.

In one configuration of the method, the first electrical contact region and the second electrical contact region can be formed on or above a common, electrically conductive substrate.

In one configuration of the method, the second electrical contact region can be formed with a larger layer thickness than the first electrical contact region.

In one configuration of the method, the second electrical contact region can be formed in an elevated fashion relative to the first electrical contact region, for example in a topographically elevated fashion.

In one configuration of the method, an adhesion promoter layer can be formed as an exposed layer in the second electrical contact region. The adhesion promoter layer can be formed in such a way that the adhesion between a cohesive connection means and the layer on or above which the adhesion promoter layer is formed is increased, for example by a reduction of the adhesion work of the cohesive connection means during wetting, as a result of which the degree of wetting is increased.

In one configuration of the method, the adhesion promoter layer can be formed in an electrically conductive fashion.

In one configuration of the method, the second layer structure can be formed in such a way that the adhesion promoter layer is electrically connected to the contact pad.

In one configuration of the method, the second contact region can have a greater or lesser surface roughness than the first electrical contact region in such a way that the second contact region has a larger contact area than the first contact region in respect of the cohesive connection.

In one configuration of the method, the adhesion promoter layer may include or be formed from one of the following substances: gold, silver, copper, platinum, palladium, nickel, aluminum.

In one configuration of the method, the first electrical contact region can be formed in such a way that the exposed layer of the first layer structure is formed as an electrically conductive layer, for example includes or is formed from chromium or aluminum.

In one configuration of the method, the first layer structure can be formed in such a way that the exposed layer of the first layer structure is formed as a dielectric layer, for example a barrier thin-film layer.

In one configuration of the method, at least one part of the adhesion promoter layer of the second layer structure can be formed on or above the dielectric layer, for example by the first electrical contact region as a structured dielectric layer surrounding the second electrical contact region and the adhesion promoter layer being formed in such a way that the adhesion promoter layer overfills the structured dielectric layer.

In one configuration of the method, the part of the adhesion promoter layer on or above the dielectric layer can be cohesively and/or electrically connected to the second electrical contact region.

In one configuration of the method, the adhesion promoter layer can be cohesively connected to the dielectric layer in such a way that the physical contact of the first electrical contact region with the second electrical contact region is at least partly hermetically sealed relative to at least water and/or oxygen.

In one configuration of the method, forming the second electrical contact region can be designed forming the adhesion promoter layer on or above at least the common substrate of the first electrical contact region. In other words: in one configuration, the second contact region, apart from the adhesion promoter layer, can have the same or fewer layers than the first electrical contact region.

In one configuration of the method, forming the second electrical contact region before forming the adhesion promoter layer may include exposing an electrically conductive layer of the first electrical contact region, wherein the exposed layer is electrically connected to the contact pad. In other words: before forming the adhesion promoter layer and/or forming the second electrical contact region may include structuring the first electrical contact region, for example partly removing the dielectric layer, such that the second electrical contact region is free of the dielectric layer.

In one configuration of the method, the second electrical contact region can be designed for spatially delimiting the cohesive electrical contacting of the contact pad.

In one configuration of the method, the method can furthermore include forming an optically active region and an optically inactive region.

In one configuration of the method, forming the optically active region may include forming an electrically active region, for example forming an organic functional layer structure and at least one electrode.

In one configuration of the method, the contact pad can be formed in the optically inactive region.

In one configuration of the method, the optically active region and the optically inactive region can be formed in such a way that the contact pad is electrically connected to the electrically active region.

In one configuration of the method, the organic optoelectronic component can be formed as an organic solar cell or an organic light emitting diode.

In various embodiments, a method for cohesively electrically contacting an electrical connection structure with a contact pad of an organic optoelectronic component is provided, the method including: providing a contact pad having a first electrical contact region and a second electrical contact region; increasing the adhesion of the second electrical contact region compared with the first electrical contact region in respect of a cohesive electrical connection of a connection structure to the contact pad; forming a physically and/or an electrical contact of the electrical connection structure with the second electrical contact region; forming a cohesive connection between the electrical connection structure and the second electrical contact region.

In one configuration of the method for cohesive electrical contacting, forming the cohesive connection may include: applying a cohesive connection means on or above the second electrical contact region and/or the electrical connection structure; liquefying the cohesive connection means and solidifying the cohesive connection means.

In one configuration of the method for cohesive electrical contacting, applying the cohesive connection means can be embodied before forming the physical and/or electrical contact.

In one configuration of the method for cohesive electrical contacting, the cohesive connection means and/or the contact pad can be designed in such a way that the first contact region is free of cohesive connection means. In other words: the liquefied cohesive connection means can wets only the second electrical contact region and the electrical connection structure.

In one configuration of the method for cohesive electrical contacting, the cohesive connection means can be designed to be electrically conductive, for example as a metallic solder or an electrically conductive adhesive.

In one configuration of the method for cohesive electrical contacting, the cohesive connection means can be designed to be electrically insulating, for example as a glass solder or an adhesive.

In one configuration of the method for cohesive electrical contacting, the cohesive connection means may include a matrix with at least one type of adhesion promoter additive.

In one configuration of the method for cohesive electrical contacting, the adhesion promoter additive can be distributed in particulate form in the matrix.

In one configuration of the method for cohesive electrical contacting, the adhesion promoter additive may include or be formed from one of the following substances: gold, silver, copper, nickel, platinum, palladium, aluminum.

In one configuration of the method for cohesive electrical contacting, liquefying may include forming an electric current flow through the electrical connection.

In one configuration of the method for cohesive electrical contacting, the electric current path can be designed in such a way that the current path is closed by the contact pad.

In one configuration of the method for cohesive electrical contacting, the electric current can be designed in such a way that dielectric layers are broken down in the current path of the electrical connection.

In one configuration of the method for cohesive electrical contacting, liquefying the cohesive connection means may include irradiating the cohesive connection means with electromagnetic radiation, for example laser irradiation.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a schematic cross-sectional view of an optoelectronic component, in accordance with various embodiments;

FIG. 2 shows a schematic cross-sectional view of an optoelectronic component, in accordance with various embodiments;

FIG. 3 shows a schematic plan view of the rear side of an optoelectronic component, in accordance with various embodiments;

FIG. 4 shows a diagram concerning one method for producing an electrical component, in accordance with various configurations;

FIGS. 5A to 5F show schematic cross-sectional views of an optoelectronic component in the method for producing an optoelectronic component, in accordance with various configurations;

FIGS. 6A to 6D show schematic cross-sectional views of an optoelectronic component in the method for producing an optoelectronic component, in accordance with various configurations;

FIG. 7 shows a schematic illustration of an electrical circuit of an optoelectronic component, in accordance with various embodiments; and

FIGS. 8A to 8C show schematic illustrations of one embodiment of an optoelectronic component.

### DETAILED DESCRIPTION

In the following detailed description, reference is made to the accompanying drawings, which form part of this description and show for illustration purposes specific embodiments in which the invention can be implemented. In this regard, direction terminology such as, for instance, “at the top”, “at the bottom”, “at the front”, “at the back”, “front”, “rear”, etc. is used with respect to the orientation of the figure(s) described. Since component parts of embodiments can be positioned in a number of different orientations, the direction terminology serves for illustration and is not restrictive in any way whatsoever. It goes without saying that other embodiments can be used and structural or logical changes can be made, without departing from the scope of protection of the present invention. It goes without saying that the features of the various embodiments described herein can be combined with one another, unless specifically indicated otherwise. Therefore, the following detailed description should not be interpreted in a restrictive sense, and the scope of protection of the present invention is defined by the appended claims.

In the context of this description, the terms “connected” and “coupled” are used to describe both a direct and an indirect connection and a direct or indirect coupling. In the figures, identical or similar elements are provided with identical reference signs, insofar as this is expedient.

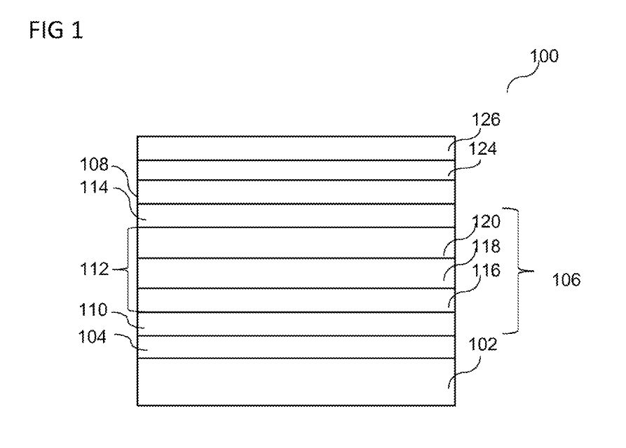

FIG. 1 shows a schematic cross-sectional view of an optoelectronic component, in accordance with various embodiments.

The optoelectronic component 100, for example an electronic component 100 which provides electromagnetic radiation, for example a light emitting component 100, for example in the form of an organic light emitting diode 100, can have a carrier 102. The carrier 102 can serve for example as a carrier element for electronic elements or layers, for example light emitting elements. By way of example, the carrier 102 may include or be formed from glass, quartz and/or a semiconductor material or any other suitable substance. Furthermore, the carrier 102 may include or be formed from a plastics film or a laminate including one or including a plurality of plastics films. The plastic may include or be formed from one or more polyolefins (for example high or low density polyethylene (PE) or polypropylene (PP)). Furthermore, the plastic may include or be formed from polyvinyl chloride (PVC), polystyrene (PS), polyester and/or polycarbonate (PC), polyethylene terephthalate (PET), polyethersulfone (PES) and/or polyethylene naphthalate (PEN). The carrier 102 may include one or more of the substances mentioned above. The carrier 102 may include or be formed from a metal or a metal compound, for example copper, silver, gold, platinum or the like.

A carrier 102 including a metal or a metal compound can also be embodied as a metal film or a metal-coated film.

The carrier 102 can be embodied as translucent or even transparent.

In various embodiments, the term “translucent” or “translucent layer” can be understood to mean that a layer is transmissive to light, for example to the light generated by the light emitting component, for example in one or more wavelength ranges, for example to light in a wavelength range of visible light (for example at least in a partial range of the wavelength range of from 380 nm to 780 nm). By way of example, in various embodiments, the term “translucent layer” should be understood to mean that substantially the entire quantity of light coupled into a structure (for example a layer) is also coupled out from the structure (for example layer), wherein part of the light can be scattered in this case.

In various embodiments, the term “transparent” or “transparent layer” can be understood to mean that a layer is transmissive to light (for example at least in a partial range of the wavelength range of from 380 nm to 780 nm), wherein light coupled into a structure (for example a layer) is also coupled out from the structure (for example layer) substantially without scattering or light conversion. Consequently, in various embodiments, “transparent” should be regarded as a special case of “translucent”.

For the case where, for example, a light emitting monochromatic or emission spectrum-limited electronic component is intended to be provided, it suffices for the optically translucent layer structure to be translucent at least in a partial range of the wavelength range of the desired monochromatic light or for the limited emission spectrum.

In various embodiments, the organic light emitting diode 100 (or else the light emitting components in accordance with the embodiments that have been described above or will be described below) can be designed as a so-called top and bottom emitter. A top and/or bottom emitter can also be designated as an optically transparent component, for example a transparent organic light emitting diode.

In various embodiments, a barrier layer 104 can optionally be arranged on or above the carrier 102. The barrier layer 104 may include or consist of one or more of the following materials: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, and mixtures and alloys thereof. Furthermore, in various embodiments, the barrier layer 104 can have a layer thickness in a range of approximately 0.1 nm (one atomic layer) to approximately 5000 nm, for example a layer thickness in a range of approximately 10 nm to approximately 200 nm, for example a layer thickness of approximately 40 nm.

An electrically active region 106 of the light emitting component 100 can be arranged on or above the barrier layer 104. The electrically active region 106 can be understood as that region of the light emitting component 100 in which an electric current for the operation of the light emitting component 100 flows. In various embodiments, the electrically active region 106 may include a first electrode 110, a second electrode 114 and an organic functional layer structure 112, as are explained in even greater detail below.

In this regard, in various embodiments, the first electrode 110 (for example in the form of a first electrode layer 110) can be applied on or above the barrier layer 104 (or, if the barrier layer 104 is not present, on or above the carrier 102). The first electrode 110 (also designated hereinafter as bottom electrode 110) can be formed from an electrically conductive substance, such as, for example, a metal or a transparent conductive oxide (TCO) or a layer stack including a plurality of layers of the same metal or different metals and/or the same TCO or different TCOs. Transparent conductive oxides are transparent conductive substances, for example metal oxides, such as, for example, zinc oxide, tin oxide, cadmium oxide, titanium oxide, indium oxide, or indium tin oxide (ITO). Alongside binary metal-oxygen compounds, such as, for example, ZnO, SnO₂, or In₂O₃, ternary metal-oxygen compounds, such as, for example, AlZnO, Zn₂SnO₄, CdSnO₃, ZnSnO₃, MgIn₂O₄, GaInO₃, Zn₂In₂O₅ or In₄Sn₃O₁₂, or mixtures of different transparent conductive oxides also belong to the group of TCOs and can be used in various embodiments. Furthermore, the TCOs do not necessarily correspond to a stoichiometric composition and can furthermore be p-doped or n-doped.

In various embodiments, the first electrode 110 may include a metal; for example Ag, Pt, Au, Mg, Al, Ba, In, Ca, Sm or Li, and compounds, combinations or alloys of these materials.

In various embodiments, the first electrode 110 can be formed by a layer stack of a combination of a layer of a metal on a layer of a TCO, or vice versa. One example is a silver layer applied on an indium tin oxide layer (ITO) (Ag on ITO) or ITO-Ag-ITO multilayers.

In various embodiments, the first electrode 110 may include one or a plurality of the following substances as an alternative or in addition to the abovementioned substances: networks composed of metallic nanowires and nanoparticles, for example composed of Ag; networks composed of carbon nanotubes; graphene particles and graphene layers; networks composed of semiconducting nanowires.

Furthermore, the first electrode 110 may include electrically conductive polymers or transition metal oxides or transparent electrically conductive oxides.

In various embodiments, the first electrode 110 and the carrier 102 can be formed as translucent or transparent. In the case where the first electrode 110 includes or is formed from a metal, the first electrode 110 can have for example a layer thickness of less than or equal to approximately 25 nm, for example a layer thickness of less than or equal to approximately 20 nm, for example a layer thickness of less than or equal to approximately 18 nm. Furthermore, the first electrode 110 can have for example a layer thickness of greater than or equal to approximately 10 nm, for example a layer thickness of greater than or equal to approximately 15 nm. In various embodiments, the first electrode 110 can have a layer thickness in a range of approximately 10 nm to approximately 25 nm, for example a layer thickness in a range of approximately 10 nm to approximately 18 nm, for example a layer thickness in a range of approximately 15 nm to approximately 18 nm.

Furthermore, for the case where the first electrode 110 includes or is formed from a transparent conductive oxide (TCO), the first electrode 110 can have for example a layer thickness in a range of approximately 50 nm to approximately 500 nm, for example a layer thickness in a range of approximately 75 nm to approximately 250 nm, for example a layer thickness in a range of approximately 100 nm to approximately 150 nm.

Furthermore, for the case where the first electrode 110 is formed from, for example, a network composed of metallic nanowires, for example composed of Ag, which can be combined with conductive polymers, a network composed of carbon nanotubes which can be combined with conductive polymers, or from graphene layers and composites, the first electrode 110 can have for example a layer thickness in a range of approximately 1 nm to approximately 500 nm, for example a layer thickness in a range of approximately 10 nm to approximately 400 nm, for example a layer thickness in a range of approximately 40 nm to approximately 250 nm.

The first electrode 110 can be formed as an anode, that is to say as a hole-injecting electrode, or as a cathode, that is to say as an electron-injecting electrode.

The first electrode 110 can have a first electrical contact pad, to which a first electrical potential (provided by an energy source (not illustrated), for example a current source or a voltage source) can be applied. Alternatively, the first electrical potential can be applied to the carrier 102 and then be fed indirectly to the first electrode 110 via said carrier. The first electrical potential can be, for example, the ground potential or some other predefined reference potential.

Furthermore, the electrically active region 106 of the light emitting component 100 can have an organic functional layer structure 112, which is applied or formed on or above the first electrode 110.

The organic functional layer structure 112 may include one or a plurality of emitter layers 118, for example including fluorescent and/or phosphorescent emitters, and one or a plurality of hole-conducting layers 116 (also designated as hole transport layer(s) 120). In various embodiments, one or a plurality of electron-conducting layers 116 (also designated as electron transport layer(s) 116) can alternatively or additionally be provided.

Examples of emitter materials which can be used in the light emitting component 100 in accordance with various embodiments for the emitter layer(s) 118 include organic or organometallic compounds such as derivatives of polyfluorene, polythiophene and polyphenylene (e.g. 2- or 2,5-substituted poly-p-phenylene vinylene) and metal complexes, for example iridium complexes such as blue phosphorescent FIrPic (bis(3,5-difluoro-2-(2-pyridyl)phenyl(2-carboxypyridyl) iridium III), green phosphorescent Ir(ppy)₃ (tris(2-phenylpyridine)iridium III), red phosphorescent Ru (dtb-bpy)₃*2(PF₆) (tris[4,4′-di-tert-butyl-(2,2′)-bipyridine]ruthenium(III) complex) and blue fluorescent DPAVBi (4,4-bis[4-(di-p-tolylamino)styryl]biphenyl), green fluorescent TTPA (9,10-bis[N,N-di(p-tolyl)amino]anthracene) and red fluorescent DCM2 (4-dicyanomethylene)-2-methyl-6-julolidyl-9-enyl-4H-pyran) as non-polymeric emitters. Such non-polymeric emitters can be deposited by means of thermal evaporation, for example. Furthermore, it is possible to use polymer emitters, which can be deposited, in particular, by means of a wet-chemical method such as spin coating, for example.

The emitter materials can be embedded in a matrix material in a suitable manner.

It should be pointed out that other suitable emitter materials are likewise provided in other embodiments.

The emitter materials of the emitter layer(s) 118 of the light emitting component 100 can be selected for example such that the light emitting component 100 emits white light. The emitter layer(s) 118 may include a plurality of emitter materials that emit in different colors (for example blue and yellow or blue, green and red); alternatively, the emitter layer(s) 118 can also be constructed from a plurality of partial layers, such as a blue fluorescent emitter layer 118 or blue phosphorescent emitter layer 118, a green phosphorescent emitter layer 118 and a red phosphorescent emitter layer 118. By mixing the different colors, the emission of light having a white color impression can result. Alternatively, provision can also be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary and secondary radiation.

The organic functional layer structure 112 can generally include one or a plurality of electroluminescent layers. The one or the plurality of electroluminescent layers may include organic polymers, organic oligomers, organic monomers, organic small, non-polymeric molecules (“small molecules”) or a combination of these materials. By way of example, the organic functional layer structure 112 may include one or a plurality of electroluminescent layers embodied as a hole transport layer 120, so as to enable for example in the case of an OLED an effective hole injection into an electroluminescent layer or an electroluminescent region. Alternatively, in various embodiments, the organic functional layer structure 112 may include one or a plurality of functional layers embodied as an electron transport layer 116, so as to enable for example in an OLED an effective electron injection into an electroluminescent layer or an electroluminescent region. By way of example, tertiary amines, carbazole derivatives, conductive polyaniline or polyethylene dioxythiophene can be used as material for the hole transport layer 120. In various embodiments, the one or the plurality of electroluminescent layers can be embodied as an electroluminescent layer.

In various embodiments, the hole transport layer 120 can be applied, for example deposited, on or above the first electrode 110, and the emitter layer 118 can be applied, for example deposited, on or above the hole transport layer 120. In various embodiments, the electron transport layer 116 can be applied, for example deposited, on or above the emitter layer 118.

In various embodiments, the organic functional layer structure 112 (that is to say for example the sum of the thicknesses of hole transport layer(s) 120 and emitter layer(s) 118 and electron transport layer(s) 116) can have a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various embodiments, the organic functional layer structure 112 can have for example a stack of a plurality of organic light emitting diodes (OLEDs) arranged directly one above another, wherein each OLED can have for example a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various embodiments, the organic functional layer structure 112 can have for example a stack of two, three or four OLEDs arranged directly one above another, in which case for example the organic functional layer structure 112 can have a layer thickness of a maximum of approximately 3 μm.

The light emitting component 100 can optionally generally include further organic functional layers, for example arranged on or above the one or the plurality of emitter layers 118 or on or above the electron transport layer(s) 116, which serve to further improve the functionality and thus the efficiency of the light emitting component 100.

The second electrode 114 (for example in the form of a second electrode layer 114) can be applied on or above the organic functional layer structure 112 or, if appropriate, on or above the one or the plurality of further organic functional layer structures.

In various embodiments, the second electrode 114 may include or be formed from the same substances as the first electrode 110, metals being particularly suitable in various embodiments.

In various embodiments, the second electrode 114 (for example for the case of a metallic second electrode 114) can have for example a layer thickness of less than or equal to approximately 50 nm, for example a layer thickness of less than or equal to approximately 45 nm, for example a layer thickness of less than or equal to approximately 40 nm, for example a layer thickness of less than or equal to approximately 35 nm, for example a layer thickness of less than or equal to approximately 30 nm, for example a layer thickness of less than or equal to approximately 25 nm, for example a layer thickness of less than or equal to approximately 20 nm, for example a layer thickness of less than or equal to approximately 15 nm, for example a layer thickness of less than or equal to approximately 10 nm.

The second electrode 114 can generally be formed in a similar manner to the first electrode 110, or differently than the latter. In various embodiments, the second electrode 114 can be formed from one or more of the substances and with the respective layer thickness, as described above in connection with the first electrode 110. In various embodiments, both the first electrode 110 and the second electrode 114 are formed as translucent or transparent. Consequently, the light emitting component 100 illustrated in FIG. 1 can be designed as a top and bottom emitter (to put it another way as a transparent light emitting component 100).

The second electrode 114 can be formed as an anode, that is to say as a hole-injecting electrode, or as a cathode, that is to say as an electron-injecting electrode.

The second electrode 114 can have a second electrical connection structure, to which a second electrical potential (which is different than the first electrical potential), provided by the energy source, can be applied. The second electrical potential can have for example a value such that the difference with respect to the first electrical potential has a value in a range of approximately 1.5 V to approximately 20 V, for example a value in a range of approximately 2.5 V to approximately 15 V, for example a value in a range of approximately 3 V to approximately 12 V.

An encapsulation 108, for example in the form of a barrier thin-film layer/thin-film encapsulation 108, can optionally also be formed on or above the second electrode 114 and thus on or above the electrically active region 106.

In the context of this application, a “barrier thin-film layer” 108 or a “barrier thin film” 108 can be understood to mean, for example, a layer or a layer structure which is suitable for forming a barrier against chemical impurities or atmospheric substances, in particular against water (moisture) and oxygen. In other words, the barrier thin-film layer 108 is formed in such a way that OLED-damaging substances such as water, oxygen or solvent cannot penetrate through it or at most very small proportions of said substances can penetrate through it.

In accordance with one configuration, the barrier thin-film layer 108 can be formed as an individual layer (to put it another way, as a single layer). In accordance with an alternative configuration, the barrier thin-film layer 108 may include a plurality of partial layers formed one on top of another. In other words, in accordance with one configuration, the barrier thin-film layer 108 can be formed as a layer stack. The barrier thin-film layer 108 or one or a plurality of partial layers of the barrier thin-film layer 108 can be formed for example by means of a suitable deposition method, e.g. by means of an atomic layer deposition (ALD) method in accordance with one configuration, e.g. a plasma enhanced atomic layer deposition (PEALD) method or a plasmaless atomic layer deposition (PLALD) method, or by means of a chemical vapor deposition (CVD) method in accordance with another configuration, e.g. a plasma enhanced chemical vapor deposition (PECVD) method or a plasmaless chemical vapor deposition (PLCVD) method, or alternatively by means of other suitable deposition methods.

By using an atomic layer deposition (ALD) method, it is possible for very thin layers to be deposited. In particular, layers having layer thicknesses in the atomic layer range can be deposited.

In accordance with one configuration, in the case of a barrier thin-film layer 108 having a plurality of partial layers, all the partial layers can be formed by means of an atomic layer deposition method. A layer sequence including only ALD layers can also be designated as a “nanolaminate”.

In accordance with an alternative configuration, in the case of a barrier thin-film layer 108 including a plurality of partial layers, one or a plurality of partial layers of the barrier thin-film layer 108 can be deposited by means of a different deposition method than an atomic layer deposition method, for example by means of a vapor deposition method.

In accordance with one configuration, the barrier thin-film layer 108 can have a layer thickness of approximately 0.1 nm (one atomic layer) to approximately 1000 nm, for example a layer thickness of approximately 10 nm to approximately 100 nm in accordance with one configuration, for example approximately 40 nm in accordance with one configuration.

In accordance with one configuration in which the barrier thin-film layer 108 includes a plurality of partial layers, all the partial layers can have the same layer thickness. In accordance with another configuration, the individual partial layers of the barrier thin-film layer 108 can have different layer thicknesses. In other words, at least one of the partial layers can have a different layer thickness than one or more other partial layers.

In accordance with one configuration, the barrier thin-film layer 108 or the individual partial layers of the barrier thin-film layer 108 can be formed as a translucent or transparent layer. In other words, the barrier thin-film layer 108 (or the individual partial layers of the barrier thin-film layer 108) can consist of a translucent or transparent substance (or a substance mixture that is translucent or transparent).

In accordance with one configuration, the barrier thin-film layer 108 or (in the case of a layer stack having a plurality of partial layers) one or a plurality of the partial layers of the barrier thin-film layer 108 may include or consist of one of the following substances: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, and mixtures and alloys thereof. In various embodiments, the barrier thin-film layer 108 or (in the case of a layer stack having a plurality of partial layers) one or a plurality of the partial layers of the barrier thin-film layer 108 may include one or a plurality of high refractive index materials, to put it another way one or a plurality of materials having a high refractive index, for example having a refractive index of at least 2.

In one configuration, the cover 126, for example composed of glass, can be applied for example by means of frit bonding (glass frit bonding/glass soldering/seal glass bonding) to the barrier thin-film layer 108 by means of a conventional glass solder in the geometrical edge regions of the organic optoelectronic component 100.

In various embodiments, on or above the barrier thin-film layer 108, it is possible to provide an adhesive and/or a protective lacquer 124, by means of which, for example, a cover 126 (for example a glass cover 126, a metal film covering 126, a sealed plastics film cover 126) is fixed, for example adhesively bonded, on the barrier thin-film layer 108. In various embodiments, the optically translucent layer composed of adhesive and/or protective lacquer 124 can have a layer thickness of greater than 1 μm, for example a layer thickness of several μm. In various embodiments, the adhesive may include or be a lamination adhesive.

In various embodiments, light-scattering particles can also be embedded into the layer of the adhesive (also designated as adhesive layer), which particles can lead to a further improvement in the color angle distortion and the coupling-out efficiency. In various embodiments, the light-scattering particles provided can be dielectric scattering particles, for example, such as metal oxides, for example, such as e.g. silicon oxide (SiO₂), zinc oxide (ZnO), zirconium oxide (ZrO₂), indium tin oxide (ITO) or indium zinc oxide (IZO), gallium oxide (Ga₂Oa), aluminum oxide, or titanium oxide. Other particles may also be suitable provided that they have a refractive index that is different than the effective refractive index of the matrix of the translucent layer structure, for example air bubbles, acrylate, or hollow glass beads. Furthermore, by way of example, metallic nanoparticles, metals such as gold, silver, iron nanoparticles, or the like can be provided as light-scattering particles.

In various embodiments, between the second electrode 114 and the layer composed of adhesive and/or protective lacquer 124, an electrically insulating layer (not shown) can also be applied, for example SiN, for example having a layer thickness in a range of approximately 300 nm to approximately 1.5 μm, for example having a layer thickness in a range of approximately 500 nm to approximately 1 μm, in order to protect electrically unstable materials, during a wet-chemical process for example.

In various embodiments, the adhesive can be designed in such a way that it itself has a refractive index which is less than the refractive index of the cover 126. Such an adhesive can be for example a low refractive index adhesive such as, for example, an acrylate which has a refractive index of approximately 1.3. In one configuration, an adhesive can be for example a high refractive index adhesive which includes for example high refractive index, non-scattering particles and has a mean refractive index corresponding approximately to the mean refractive index of the organic functional layer structure, for example in a range of approximately 1.7 to approximately 2.0. Furthermore, a plurality of different adhesives forming an adhesive layer sequence can be provided.

Furthermore, it should be pointed out that, in various embodiments, an adhesive 124 can also be completely dispensed with, for example in configurations in which the cover 126, for example composed of glass, is applied to the barrier thin-film layer 108 by means of plasma spraying, for example.

In various embodiments, the cover 126 and/or the adhesive 124 can have a refractive index (for example at a wavelength of 633 nm) of 1.55.

Furthermore, in various embodiments, one or a plurality of antireflective layers (for example combined with the encapsulation 108, for example the barrier thin-film layer 108) can additionally be provided in the light emitting component 100.

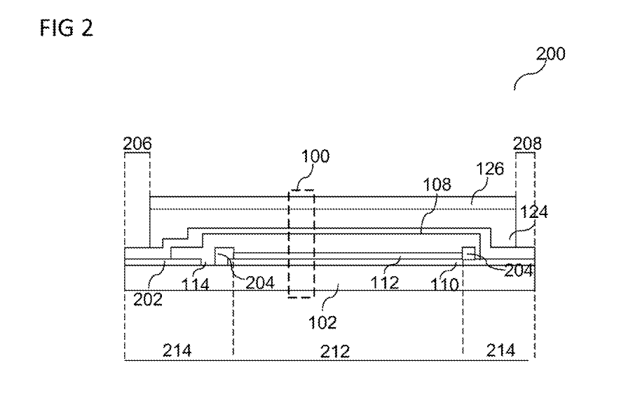

FIG. 2 shows a schematic cross-sectional view of an optoelectronic component, in accordance with various embodiments.

The schematic cross-sectional view in FIG. 2 illustrates one embodiment of an optoelectronic component in accordance with one of the configurations from the description of FIG. 1—identified by means of the excerpt 100 in the cross-sectional view 200.

The illustration shows: A first electrode 110 formed on or above a carrier 102. An organic functional layer structure 112 is formed on or above the first electrode 110. A second electrode 114 is formed above or on the organic functional layer structure 112. The second electrode 114 is electrically insulated from the first electrode 110 by means of an electrical insulation 204. The second electrode 114 can be physically and electrically connected to an electrical connection layer 202. The electrical connection layer 202 can be formed on or above the carrier 102 in the geometrical edge region of the carrier 102, for example laterally alongside the first electrode 110. The electrical connection layer 202 is electrically insulated from the first electrode 110 by means of a further electrical insulation 204. A barrier thin-film layer 108 is arranged on or above the second electrode 114 in such a way that the second electrode 114, the electrical insulations 204 and the organic functional layer structure 112 are surrounded by the barrier thin-film layer 108, that is to say are enclosed in a combination of the barrier thin-film layer 108 with the carrier 102. The barrier thin-film layer 108 can hermetically seal the enclosed layers with regard to harmful environmental influences. An adhesive layer 124 is arranged on or above the barrier thin-film layer 108 in such a way that the adhesive layer 124 areally and hermetically seals the barrier thin-film layer 108 with regard to harmful environmental influences. A cover 126 is arranged on or above the adhesive layer 124. The cover for example be adhesively bonded, for example be laminated, onto the barrier thin-film layer 108 by means of an adhesive 124.

Approximately the region of the optoelectronic component 100 with organic functional layer structure 112 on or above the carrier 102 can be designated as an optically active region 212. Approximately the region of the optoelectronic component 100 without an organic functional layer structure 112 on or above the carrier 102 can be designated as an optically inactive region 214. The optically inactive region 214 can be arranged for example in a planar fashion alongside the optically active region 212.

An optoelectronic component 100 embodied as at least translucent, for example transparent, for example including an at least translucent carrier 102, at least translucent electrodes 110, 114, an at least translucent organic functional layer system and an at least translucent barrier thin-film layer 108, may include for example two planar, optically active sides—the top side and the underside of the optoelectronic component 100 in the schematic cross-sectional view.

However, the optically active region 212 of an optoelectronic component 100 can also have only one optically active side and one optically inactive side, for example in the case of an optoelectronic component 100 designed as a top emitter or bottom emitter, for example by means of the second electrode 100 or the barrier thin-film layer 108 being embodied as reflective for electromagnetic radiation provided.

The carrier 102, the first electrode 110, the organic functional layer structure 112, the second electrode 114, the barrier thin-film layer 108, the adhesive layer 124 and the cover 126 can be designed for example in accordance with one of the configuration from the descriptions of FIG. 1.

The electrical insulations 204 are designed in such a way as to prevent a current flow between two electrically conductive regions, for example between the first electrode 110 and the second electrode 114. The substance or the substance mixture of the electrical insulation can be for example a covering or a coating agent, for example a polymer and/or a lacquer. The lacquer may include for example a coating substance that can be applied in liquid form or in pulverulent form, for example may include or be formed from a polyimide. The electrical insulations 204 can be applied or formed for example by means of a printing method, for example in lithographically structured fashion. The printing method may include for example inkjet printing, screen printing and/or pad printing.

The electrical connection layer 202 may include or be formed from, as substance or substance mixture, a substance or a substance mixture similar to that of the electrodes 110, 114 in accordance with one of the configurations from the descriptions of FIG. 1.

The optically inactive region 214 can have for example contact pads 206, 208 for electrically contacting the organic functional layer structure 112. In other words: In the geometrical edge region, the optoelectronic component 100 can be embodied in such a way that contact pads 206, 208 are formed for electrically contacting the optoelectronic component 100, for example by means of electrically conductive layers, for example electrical connection layers 202, electrodes 110, 114 or the like, being at least partly exposed in the region of the contact pads 206, 208 (not illustrated).

A contact pad 206, 208 can be electrically and/or physically connected to an electrode 110, 114, for example by means of a connection layer 202. However, a contact pad 206, 208 can also be designed as a region of an electrode 110, 114 or of a connection layer 202.

The contact pads 206, 208 may include or be formed from, as substance or substance mixture, a substance or a substance mixture similar to that of the second electrode 114 in accordance with one of the configurations from the descriptions of FIG. 1, for example as a metal layer structure including at least one chromium layer and at least one aluminum layer, for example chromium-aluminum-chromium (Cr—Al—Cr).

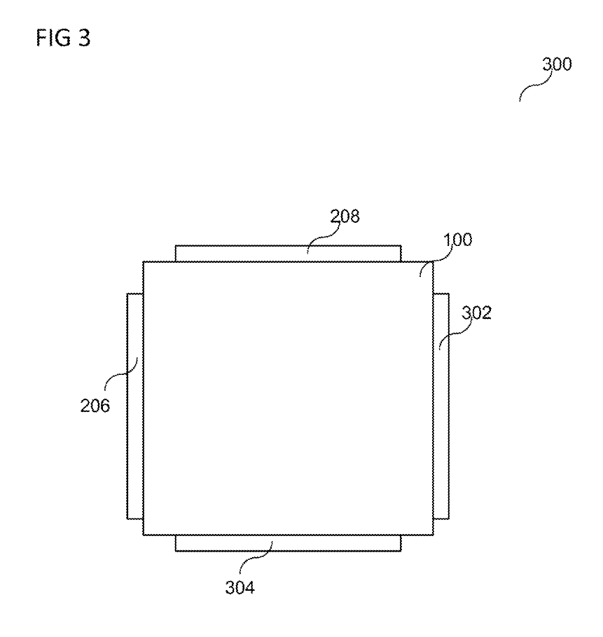

FIG. 3 shows a schematic plan view of the rear side of an optoelectronic component, in accordance with various embodiments.

FIG. 3 schematically illustrates for elucidation a plan view of the rear side of one embodiment of an optoelectronic component 100 having electrical contact pads 206, 208, 302, 304 from FIG. 1 and FIG. 2. The contact pads 206, 208, 302, 304 surround approximately a layer structure of the schematic cross-sectional view 100—the planar dimensioning of the electrical insulations 204 and the difference between the area of optically inactive region 214 and contact pads 206, 208, 302, 304 is not illustrated in this view 300.

The geometrical configuration of the optoelectronic component 100 illustrated in FIG. 3, the geometrically form and the positions of the electrical contact pads 206, 208, 302, 304 should be understood as one embodiment. Other geometrical forms and more or fewer contact pads can be formed, for example 1 contact pad, contacts pads, 3 contact pads, 5 contact pads, 6 contact pads or more.

The number of contact pads can be dependent on the planar dimensionining of the optoelectronic component 100 and the demand for the planar homogeneity of the emitted or absorbed electromagnetic radiation.

Furthermore, the number and the form of the contact pads of an optoelectronic component 100 can be dependent of how many further optoelectronic components 100 are intended to be connected to said optoelectronic component 100, for example are intended to be interconnected therewith, for example in parallel or in series.

The contact pads 206, 208, 302, 304 can be electrically connected to the electrodes 110, 114 of the organic component 100, as illustrated in FIG. 2.

The contact pads 206, 208, 302, 304 can partly or wholly surround the optoelectronic component, for example laterally, for example in a ring-shaped fashion in the optically inactive region; and/or can be multilayered. In one exemplary embodiment, a contact pad can have on the top side of the contact pad an electrical connection layer connected to a different electrode than an electrical connection layer on the underside of the contact pad.

In one embodiment, at least one of the contact pads 206, 208, 302, 304, for example the contact pad 206, can have a different polarity or polarization than the other contact pads, for example 208, 302, 304. In this case, polarity or polarization can be understood to mean different exit points or entry points of charge carriers from a current source.

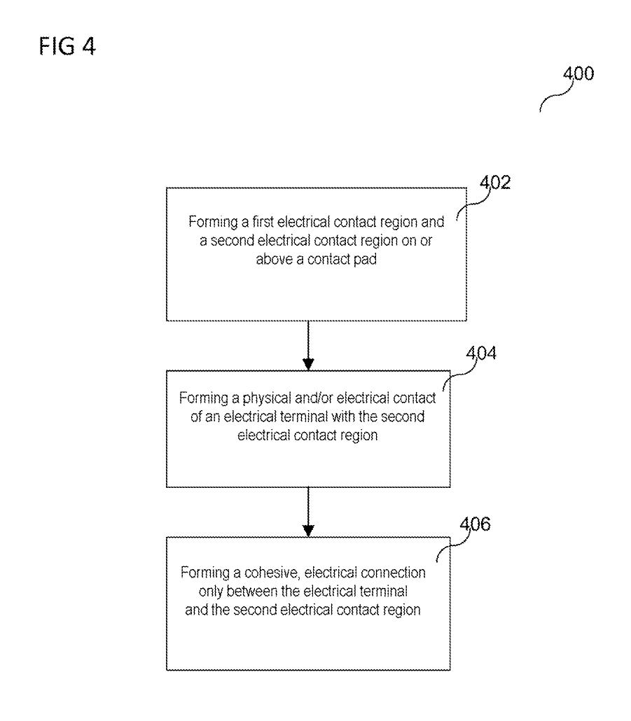

FIG. 4 shows a diagram concerning a method for producing an electrical component, in accordance with various configurations.

The method 400 may include forming 402 a first electrical contact region and a second electrical contact region on or above a contact pad.

Forming 402 a first electrical contact region and a second electrical contact region may include removing and/or forming a substance or a substance mixture on or above a contact pad.

The method 400 may include forming 404 a physical and/or electrical contact of an electrical connection structure with the second electrical contact region.

Forming 404 the physical and/or electrical contact can be designed for example as bringing about the approach of an electrical connection structure to a contact pad.

In this case, a cohesive connection means can already be formed on or above the second electrical contact region and/or the electrical connection structure. The cohesive connection means can be formed as a fusible connector, for example, and can be in a dimensionally stable state during the approaching.

The method 400 may include forming 406 a cohesive, electrical connection only between the electrical connection structure and the second electrical contact region.

Forming 406 a cohesive, electrical connection only between the electrical connection structure and the second electrical contact region may include for example liquefying or softening a cohesive connection means.

In one embodiment, liquefying the close connection means can be formed by means of an electric current, for example in that the contact pad is electrically contacted in such a way that an electric current flows only through the contact pad.

In one embodiment, the close connection means can be heated externally, for example melted by means of a laser or a soldering iron.

In one embodiment, the close connection means can be formed after the process of forming the physical contact, for example a positively locking and/or force-locking contact, of the electrical connection structure with the second electrical contact region. The close connection means can be applied for example to the positively locking and/or force-locking connection, for example can be sprayed thereon or molded around it.

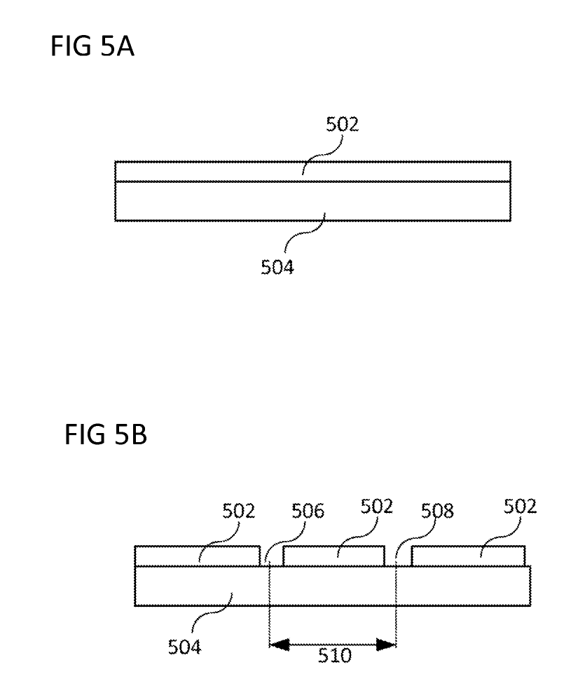

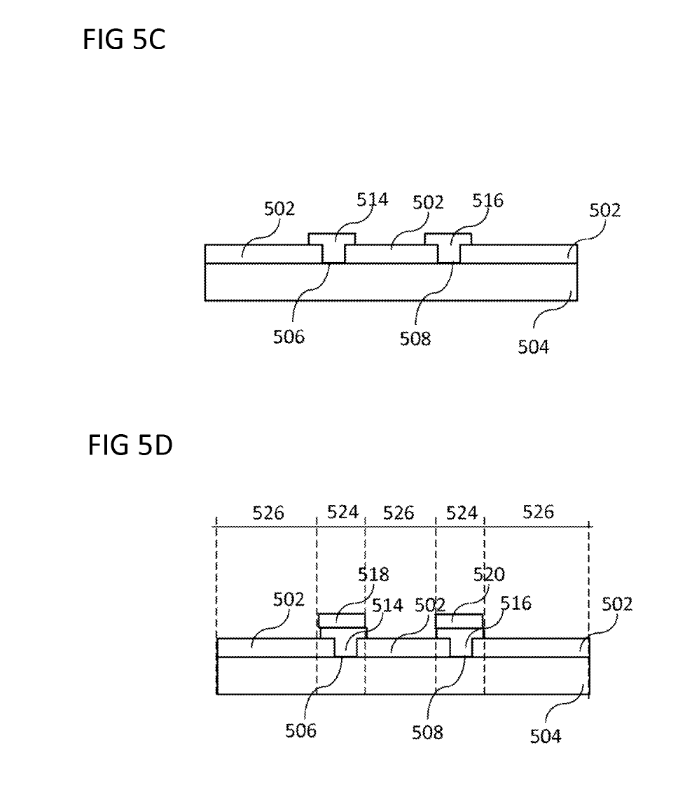

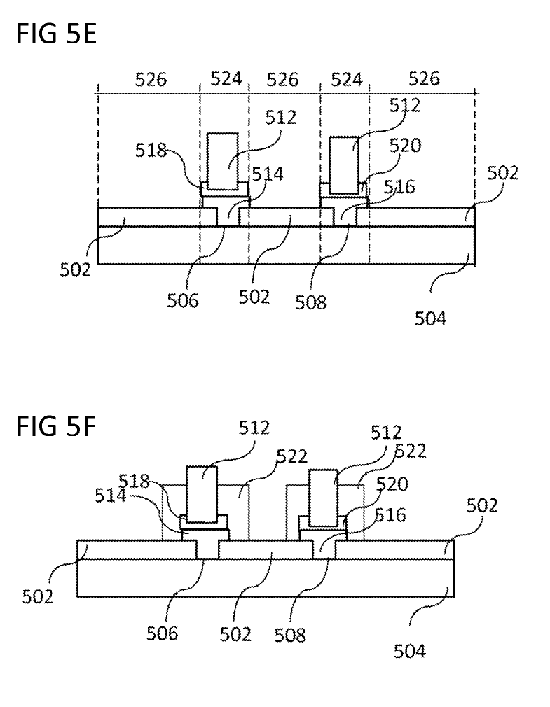

FIGS. 5A to 5F show a schematic cross-sectional view of an optoelectronic component in the method for producing an optoelectronic component, in accordance with various configurations.

FIG. 5A shows a schematic cross-sectional view of a region of a contact pad 206, 208, 302, 304 of an optoelectronic component, in accordance with various embodiments, in which an electrical connection is intended to be formed.

The region can have a dielectric layer 502 on or above an electrically conductive layer 504.

The dielectric layer 502 can generally be a dielectric layer or be designed for example in a manner similar to the barrier thin-film layer 108 of one of the configurations from the descriptions of FIG. 1 or FIG. 2.

The electrically conductive layer 504 can generally be an electrically conductive layer or be designed for example in a manner similar to the electrode 110, 114 or connection layer 202 of one of the configurations from the descriptions of FIG. 1 or FIG. 2.

The electrically conductive layer 504 can be formed in a self-supporting fashion or can be formed on a carrier 102 (not illustrated).

FIG. 5B shows a schematic cross-sectional view of a contact pad of an optoelectronic component, in accordance with various embodiments.

FIG. 5B illustrates exposed regions 506, 508 in the dielectric layer 502.

An exposed region 506, 508 can be formed by means of removing a part or a region of the dielectric layer 502 on or above the electrically conductive layer 504 in such a way that the exposed surface of the layer system including electrically conductive layer 504 and dielectric layer 502 has the electrically conductive layer 502 in an exposed region 506, 508.

The exposed regions 506, 508 can be formed after the formation of the optoelectronic component 100 by means of a mechanical process or a ballistic process.

Mechanically exposing the regions 506, 508 to be exposed can be realized by means of a glass fiber brush, for example.

Ballistically exposing the regions 506, 508 to be exposed can be realized for example by means of bombarding a region to be exposed with particles, molecules, atoms, ions, electrons and/or photons.

Bombardment with photons can be embodied for example as laser with a wavelength in a range of approximately 200 nm to approximately 1700 nm, for example can be embodied in a focused manner, for example with a focus diameter in a range of approximately 10 μm to approximately 2000 μm, for example in a pulsed manner, for example with a pulse duration in a range of approximately 100 fs to approximately 0.5 ms, for example with a power of approximately 50 mW to approximately 1000 mW, for example with a power density of approximately 100 kW/cm² to approximately 10 GW/cm², and for example with a repetition rate in a range of approximately 100 Hz to approximately 1000 Hz.

One or a plurality of exposed regions 506, 508 at a distance 510 from one another can be formed on a contact pad, wherein the distance 510 between the exposed regions and the position of the exposed regions on a contact pad can be formed differently relative to other contact pads and/or further exposed regions of the same contact pad (not illustrated).

The distance 510 between the exposed regions 506, 508 can be embodied in a range of approximately 100 μm to approximately 10 cm, for example in a range of 1 mm to approximately 5 cm, for example in a range of approximately 5 mm to approximately 2 cm.

The exposed regions 506, 508 can have or be similar to a geometrical form or a part of a geometrical form from the group of the following geometrical bodies: cylinder, cone, truncated cone, sphere, hemisphere, cube, parallelepiped, pyramid, truncated pyramid, prism, or a polyhedron.

The conductive regions 504 of the component can also be exposed at the top side or the sides of the component 200 on an optically inactive side, for example of the optically active region 212, and/or an optically inactive region 214, for example in the region of the mount of the component. Exposing regions 506, 508 can therefore be formed at all sides of the component and also at a plurality of sides simultaneously.

An exposed region can as a depression having a planar dimensioning in a range of approximately 0.01 mm² to approximately 1 cm² and a height which can correspond to the thickness of the encapsulation layer 108.

The exposed regions 506, 508 can have an identical or a different cross section, for example geometrical form, among one another.

FIG. 5C shows a schematic cross-sectional view of an electrical, cohesive connection of an optoelectronic component to electrical contacts before the coupling, in accordance with various embodiments.

In the exposed region 506, 508, a second electrically conductive layer 514, 516 can be formed on or above the electrically conductive layer 504 and/or the dielectric layer 502.

In one embodiment, the second electrically conductive layer 514, 516 can be formed as a spatially delimited, thin metallization layer on the non-solderable contact pads, i.e. on the non-solderable electrically conductive layer 504. The applied metallization layer may include for example a solderable metal, for example copper, silver, gold, aluminum, or an adhesively bondable substance.

Spatially delimiting the applied second electrically conductive layer 514, 516 can prevent for example flowing of a soldering tin as cohesive connection means. In other words: an applied metallization layer can realize a soldering resist, for example by virtue of the fact that a copper point as metallization layer accepts a solder and, for example, chromium of the electrically conductive layer 504 and the dielectric layer 502 do not.

Selective, spatially delimited formation of the second electrically conductive layer 514, 516 can be realized for example by means of low temperature powder coating, a complex plasma or a plasma dust or dusty plasma or aerosol jet printing. As a result, it is possible to realize locally a low temperature loading of organic substances and organic substance mixtures, for example less than approximately 150° C., for example less than approximately 120° C., for example in a range of approximately 80° C. to approximately 100° C.

The second electrically conductive layer 514, 516 may include or be formed from copper, silver, nickel, gold, platinum, palladium and/or aluminum, for example.

The second electrically conductive layer 514, 516 can be formed in such a way that the side surfaces of the dielectric layer 502 of the exposed regions 506, 508 are hermetically sealed with regard to water, for example by the second electrically conductive layer 514, 516 at least partly surrounding the dielectric layer 502.

In one embodiments, forming 402 a first electrical contact region 526 and a second electrical contact region 524 may include forming the exposed regions 506, 508 and forming the second electrically conductive layer 514, 516 (illustrated).

The region without a second electrically conductive layer 514, 516 can be understood as the first contact region 526 and the region with the second electrically conductive layer 514, 516 can be understood as the second contact region 524.

FIG. 5D shows a prepared cohesive connection to the contact pad.

In one embodiment, on or above the second electrically conductive layer 514, 516 a cohesive connection means 518, 520 can be formed on or above the second electrically conductive layer.

The cohesive connection means 518, 520 can be formed in an electrically conductive or electrically insulating fashion.

The cohesive connection means 518, 520 can be formed for example as an adhesive or a solder, i.e. may include or be formed from organic and/or inorganic substances.

The cohesive connection means 518, 520 can have a formable state, for example can be liquid or viscous, for example a non-cured epoxy, a thermally conductive paste, for example a silver-containing paste, soldering tin or some other liquid metal.

The dielectric layer 502 can be formed in such a way that the dielectric layer 502 is formed as impermeable to the substance or the substance mixture of the cohesive connection means 518, 520.

The cohesive connection means 518, 520 can be formed in such a way that the dielectric layer 502 is not wetted by the cohesive connection means 518, 520.

Preventing wetting of the dielectric layer 502 by means of the cohesive connection means 518, 520 can be realized by means of adapting the surface tension of the substance or the substance mixture of the dielectric layer 502, the surface tension of the substance or the substance mixture of the cohesive connection means 518, 520 and/or the roughness of the dielectric layer 502.

Adapting the surface tension of the substance or the substance mixture of the dielectric layer 502 may include for example functionalization of the exposed surface of the dielectric layer 502, for example silanization, thiolation, rinsing with a solvent or the like.

FIG. 5E shows a schematic cross-sectional view of an electrical, cohesive connection of an optoelectronic component to electrical contacts after coupling, in accordance with various embodiments.

FIG. 5E illustrates a cohesive connection, after forming 404 a physical and/or electrical contact of an electrical connection structure 512 with the second electrical contact region 524 and/or after forming 406 a cohesive, electrical connection only between the electrical connection structure 512 and the second electrical contact region 524; by way of example, the cohesive connection means 518, 520 can have a formable or dimensionally stable state.

The electrical connection structure 512 can be formed for example as a region of a cable, of an electromechanical connector or of an electronic component.

In order to simplify the orientation of the electrical terminals 512, the contacting end of the terminals 512 can be embodied as flat or tapering, for example conical or spherical (not shown).

In the case of an electrically conductive cohesive connection means 518, 520, by means of the physical contact of an electrical connection structure 512 with the cohesive connection means 518, 520, it is possible to form an electrical connection between the electrical connection structure 512 and the second electrically conductive layer 514, 516. As a result, the dimensioning of the electrical connection structure 512 can be smaller than the dimensioning of the exposed regions 506, 508 and/or of the second electrically conductive layer 514, 516. As a result, it is possible to simplify the orientation of the electrical connection structure 512 relative to the second electrical contact region 524 or the exposed regions 506, 508.

In the case of an electrically nonconductive cohesive connection means 518, 520, it is possible to form an electrical connection between an electrical connection structure 512 and the second electrical contact region 524 by means of a physical contact of the electrical connection structure 512 with the second electrically conductive layer 514, 516.

The exposed surface of the second electrically conductive layer 514, 516 can have an orienting effect for the electrical terminals 512, for example during the process of the electrical connection structure 512 approaching the second electrical contact region 524.

In this case, an orienting effect can be understood to mean a reduction of deviations of the orientation from the at least partly complementary form of the electrical connection structure 512 relative to the respective second electrical contact region 524 by means of a lateral force action by means of the form of the electrical connection structure 512 or the second electrically conductive layer 514, 516 and/or the cohesive connection means 518, 520.

FIG. 5F shows a schematic cross-sectional view of an electrical, cohesive connection of an optoelectronic component to electrical contacts after coupling, in accordance with various embodiments.

The illustration shows an electrical, cohesive connection of an electrical connection structure 512 to a second electrical contact region 524 by means of a cohesive connection means 518, 520.

In one embodiment, the cohesive connection can be encapsulated by means of an encapsulation means 522.

The encapsulation means 522 can be designed and/or embodied for example in a manner similar or identical to the electrical insulation 204 of a configuration from the description of FIG. 2.

The encapsulation means 522 can be for example hermetically impermeable with regard to water and/or oxygen.

The encapsulation means 522 can be electrically insulating, for example.

The encapsulation means 522 can be formed at low temperatures for example in a manner similar or identical to the second electrical layer 514, 516.

The encapsulation means 522 may include for example a metal oxide, an organic substance or an organic substance mixture, for example a plastic, for example an epoxy, an acrylate or the like.

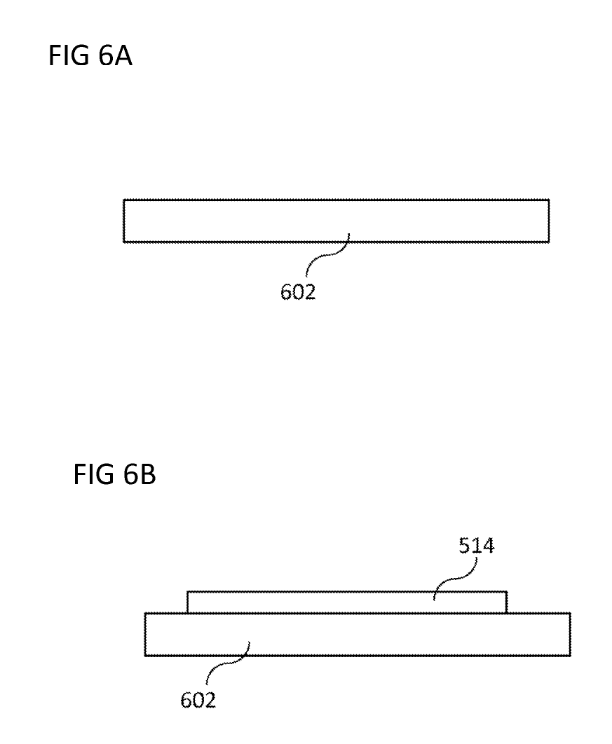

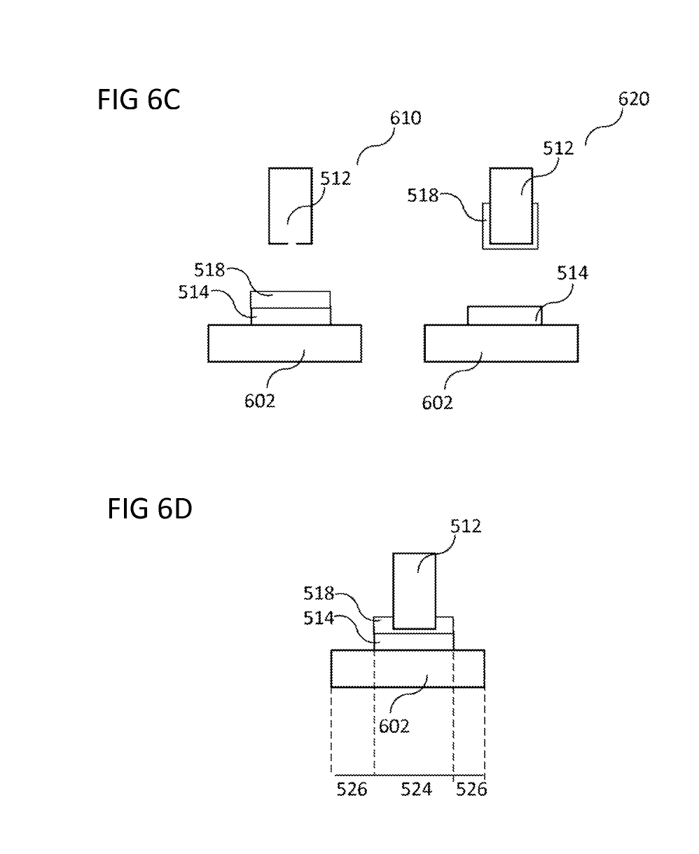

FIGS. 6A to 6D show a schematic cross-sectional view of an optoelectronic component in the method for producing an optoelectronic component, in accordance with various configurations.
6A shows a schematic cross-sectional view of a region of a contact pad 206, 208, 502, 504 of an optoelectronic component, in accordance with various embodiments, in which an electrical connection is intended to be formed.

The region can have an electrically conductive layer 602. The electrically conductive layer 602 can generally be an electrically conductive layer or can be designed for example in a manner similar to the electrode 110, 114, the connection layer 202 or the electrically conductive layer 504 of one of the configurations from the descriptions of FIG. 1, FIG. 2 or FIGS. 5A to 5F.

The electrically conductive region 602 can be formed in a self-supporting fashion or can be formed on a carrier 102 (not illustrated).

FIG. 6B shows a schematic cross-sectional view of an electrical, cohesive connection of an optoelectronic component to electrical contacts before coupling, in accordance with various embodiments.

A second electrically conductive layer 514 can be formed on or above the electrically conductive layer 602, for example formed in a manner similar to one of the configurations of the second electrically conductive layer 514 from the description of FIGS. 5A to 5F.

Spatially delimiting the applied second electrically conductive layer 514 can prevent for example flowing of a soldering tin as cohesive connection means. In other words: an applied metallization layer can realize a soldering resist, for example by virtue of the fact that a copper point as metallization layer accepts a solder and, for example, chromium of the electrically conductive layer 504 does not.

Selective, spatially delimited formation of the second electrically conductive layer 514 can be realized for example by means of low temperature powder coating, a complex plasma or a plasma dust or aerosol jet printing. As a result, it is possible to realize locally a low temperature loading of organic substances and organic substance mixtures, for example less than approximately 150° C., for example less than approximately 120° C., for example in a range of approximately 80° C. to approximately 100° C.

FIG. 6C shows prepared cohesive connections of an of an electrical connection structure to a contact pad.

A cohesive connection means 518 can be formed on or above the second electrically conductive layer 514 (illustrated in view 610) and/or on or above the electrical connection structure 512 (illustrated in view 620).

The cohesive connection means 518 can be formed for example in a manner similar to one of the configurations of the cohesive connection means 518, 520 from the description of FIGS. 5A to 5F.

The electrical connection structure 512 can be formed for example in a manner similar to one of the configurations of the electrical connection structure 512 from the description of FIGS. 5A to 5F.

FIG. 6D shows a schematic cross-sectional view of an electrical, cohesive connection of an optoelectronic component to electrical contacts after coupling, in accordance with various embodiments.

FIG. 6D illustrates a cohesive connection, after forming 404 a physical and/or electrical contact of an electrical connection structure 512 with the second electrical contact region 524 and/or after forming 406 a cohesive, electrical connection only between the electrical connection structure 512 and the second electrical contact region 524.

In one embodiment, the cohesive connection can be encapsulated by means of an encapsulation means, for example in a manner similar to one of the configurations from the description of FIGS. 5A to 5F.

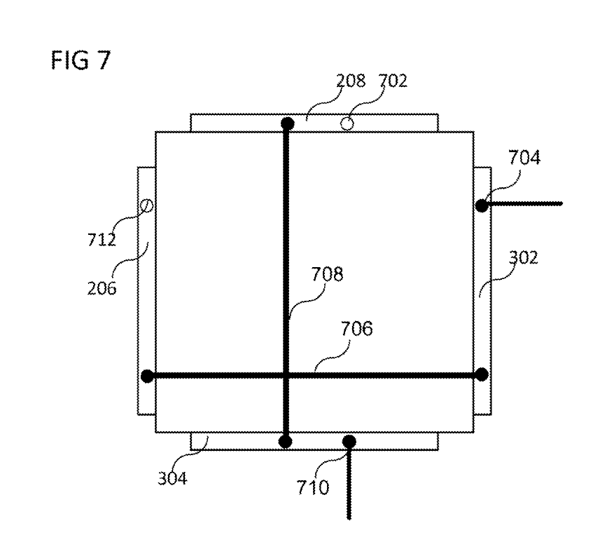

FIG. 7 shows a schematic illustration of an electrical circuit of an optoelectronic component, in accordance with various embodiments.

FIG. 7 illustrates one embodiment concerning the electrical contacting of an organic optoelectronic component with a plurality of contact pads of identical polarity, wherein an electrical connection to an external power supply is not necessary for every electrical contact pad 206, 208, 502, 304—indicated by means of the electrical terminals 704, 710.

Electrical contact pads 206, 208, 302, 304 of identical polarity, for example the contact pads 206, 302, and 208, 304; can be electrically, cohesively connected to one another by means of electrical bridges 706, 708, for example with conventional wirings with cohesive connection at the optically inactive component underside (if present) or optically inactive edge regions of the component.

Defined position for the electrical bridges 706, 708 and electrical terminals 704, 710 can be realized by means of the second electrical contact regions 524, 702, 712. The defined positions can be used for example for forming the bridges 706, 708 in an automated manner and/or simplify the parallel connection of the contact pads 206, 302, and 208, 304, since only ever one wiring element 706, 708, for example one cable, is processed or held per soldering location. This makes it possible to solder a plurality of cables for example for bridging contact pads without detaching existing cable soldered joints.

With a plurality of exposed regions 506, 508, on the contact pads 302, 304 connected to the electrical terminals 704, 710, by means of the electrical bridges 706, 708, it is also possible to simultaneously energize more than one contact pad 206, 208 of identical polarity with a respective electrical connection structure 704, 710.

It is possible for second electrical contact regions 524 that are not required application-specifically not to be formed, to be electrically insulated, to be used for testing, for orienting and/or for fixing the organic optoelectronic component.

In one embodiment, the configuration of the second electrical contact regions 524 on or above the contact pads 206, 208, 302, 304 can be designed as protection against polarity reversal in such a way that an electrical connection can be formed only in the event of corresponding polarity of electrical terminals and electrical contact regions.

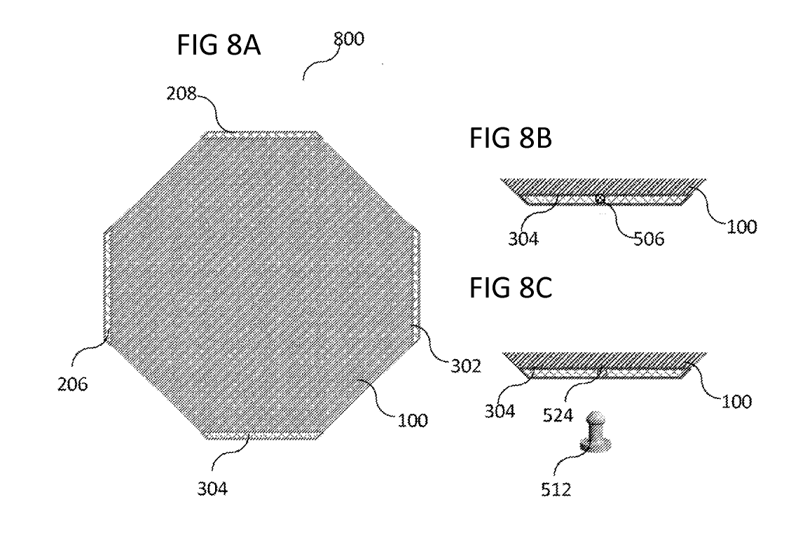

FIGS. 8A to 8C show a schematic illustration of one embodiment of an optoelectronic component.

The illustration shows one embodiment of an optoelectronic component 100 as an organic light emitting diode 800—illustrated in FIG. 8A.

The organic light emitting diode 800 can have for example a planar dimensioning in a range of approximately 50 cm² to approximately 100 cm².

The organic light emitting diode 800 can be formed in a manner similar to one of the configurations from the description of FIG. 1, FIG. 2 and/or FIG. 3.

FIG. 8B illustrates an enlarged view of a contact pad 304.

By means of a focused laser beam, it is possible to remove a part of the barrier thin-film layer 108 on or above an electrode 110, 114 and/or an electrical connection structure 202, i.e. it is possible to form an exposed region 506 in a manner similar to one of the configurations from the description of FIGS. 5A to 5F.

The focused laser beam can be embodied for example as a laser, for example having a wavelength of approximately 248 nm with a focus diameter of approximately 400 μm with a pulse duration of approximately 15 ns and an energy of approximately 18 mJ.

The planar dimensioning and the form of the exposed region 506, 508 can be set by means of the degree of focusing, i.e. the diameter of the focal point of the laser beam and the convergence thereof, and the power of the beam source.

The electrical connection of the contact pad 206 to the electrical connection structure 512, for example an electromechanical terminal pin 512, can be formed as an electrical, cohesive connection in accordance with FIGS. 5A to 5F.

For this purpose, a second electrical contact region 524 can be formed in the exposed region 506, which second electrical contact region can be shaped for example at least partly complementarily with respect to an electrical connection structure 512—illustrated in FIG. 8C.

The selectively applied metallization 514, 516 can be used for example as a soldering point and soldering resist for an electrical connection structure 512, for example an electromechanical connector 512. Accurate positioning (without flowing of the soldering tin) can be important for this purpose in order to enable the accuracy of fitting with respect to a complementary counterpiece.

In various embodiments, an organic optoelectronic component, an organic optoelectronic component, a method for producing an organic optoelectronic component and a method for cohesive electrical contacting are provided which make it possible to form a solderability of contact pads for electrically contacting the contact pads and, in addition, to realize a soldering resist function.

Furthermore, it is possible to use further the economic, for example cost-effective, methods for producing the carrier of the organic optoelectronic component, for example the carrier of the organic optoelectronic component.

Furthermore, soldering points can be selectively formed application-specifically by means of a back-end process, for example according to customer desire, for example for electrically contacting cables, electromechanical connectors or electronic components.

Furthermore, it is possible to use an economic, for example cost-effective, and established soldering process for applying electronic components even in the case of non-solderable contact pads.

Furthermore, the selectively applied metal layers can the instances of damage of an encapsulation layer on or above a contact pad, which are removed from the contact pad for electrical contacting, metallically and thus electrically highly conductively and potentially hermetically impermeably with regard to harmful substances, for example water, to seal.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. An organic optoelectronic component comprising:
at least one contact pad with a first electrical contact region and a second electrical contact region;
wherein the first electrical contact region and the second electrical contact region are electrically connected to the contact pad;
wherein the second electrical contact region is designed in such a way that it has a higher adhesion than the first electrical contact region in respect of a cohesive connection means with the contact pad; and
wherein the contact pad is designed in such a way that the first electrical contact region is free of cohesive connection means.

2. The organic optoelectronic component as claimed in claim 1,
wherein the first electrical contact region is formed alongside the second electrical contact region.

3. The organic optoelectronic component as claimed in claim 1,
wherein the second electrical contact region has an adhesion promoter layer as an exposed layer.

4. The organic optoelectronic component as claimed in claim 3,
wherein the adhesion promoter layer is formed in an electrically conductive fashion.

5. The organic optoelectronic component as claimed in claim 1,
wherein the first electrical contact region has a dielectric layer as an exposed layer.

6. The organic optoelectronic component as claimed in claim 5,
wherein the adhesion promoter layer is cohesively connected to the dielectric layer in such a way that the physical contact of the first electrical contact region with the second electrical contact region is at least partly hermetically sealed with regard to at least water and/or oxygen.

7. The organic optoelectronic component as claimed in claim 1,
wherein the second electrical contact region is designed for spatially delimiting the cohesive electrical contacting of the contact pad.

8. The organic optoelectronic component as claimed in claim 1,
wherein the organic optoelectronic component is formed as an organic solar cell or an organic light emitting diode.

9. A method for producing an organic optoelectronic component, the method comprising:
providing a contact pad having a first electrical contact region and a second electrical contact region;
increasing the adhesion of the second electrical contact region compared with the first electrical contact region in respect of a cohesive connection means with the contact pad; and
wherein the contact pad are designed in such a way that the first electrical contact region is free of cohesive connection means.

10. The method as claimed in claim 9,
wherein the first electrical contact region and the second electrical contact region are formed on or above a common, electrical conductive substrate.

11. The method as claimed in claim 9,
wherein an adhesion promoter layer is formed as an exposed layer in the second electrical contact region.

12. The method as claimed in claim 9,
wherein a dielectric layer is formed as an exposed layer in the first electrical contact region.

13. The method as claimed in claim 9,
wherein the organic optoelectronic component is formed as an organic solar cell or an organic light emitting diode.

14. A method for cohesively electrically contacting an electrical connection structure with a contact pad of an organic optoelectronic component, the method comprising:
providing a contact pad having a first electrical contact region and a second electrical contact region;
increasing the adhesion of the second electrical contact region compared with the first electrical contact region in respect of a cohesive electrical connection of a connection structure to the contact pad;
forming a physically and/or an electrical contact of the electrical connection structure with the second electrical contact region; and
forming a cohesive connection between the electrical connection structure and the second electrical contact region.

15. The organic optoelectronic component as claimed in claim 1,
wherein the first electrical contact region has a barrier thin film layer as an exposed layer.

16. The organic optoelectronic component as claimed in claim 1,
wherein the second electrical contact region is designed as a soldering resist.

17. The method as claimed in claim 12,
wherein the dielectric layer is a barrier thin film layer.
